(19) United States
(12) Patent Application Publication
(10) Pub. No.: US 2026/0194831 A1
(43) Pub. Date: Jul. 9, 2026

(54) DRIVE DEVICE, OPTICAL SYSTEM AND LITHOGRAPHY APPARATUS

(71) Applicant: Carl Zeiss SMT GmbH, Oberkochen (DE)

(72) Inventors: Markus HOLZ, Aalen (DE); Stefan WALZ, Schwaebisch Gmuend (DE)

(21) Appl. No.: 19/459,446

(22) Filed: Jan. 26, 2026

Related U.S. Application Data
(63) Continuation of application No. PCT/EP2024/070878, filed on Jul. 23, 2024.

(30) Foreign Application Priority Data
Aug. 1, 2023 (DE) 10 2023 207 368.4

(51) Int. Cl. G03F 7/00

(52) U.S. Cl. CPC G03F 7/70758; G03F 7/70075; G03F 7/70725

(57) ABSTRACT

A drive device is configured to drive a plurality N of actuator elements for actuating optical elements of an optical system. The drive device comprises N driver stages controlled by way of a time multiplex signal determined by a time multiplexing scheme. The respective driver stage of the N driver stages is assigned to one of the N actuator elements and a specific time slot of the time multiplex signal. The respective drive stage has an amplifier that is configured to amplify a signal component of the assigned time slot of the time multiplex signal so as to form a drive voltage for driving the assigned actuator element, with N≥2. The drive device also comprises a control loop, the feedback branch of which has a voltage divider that is able to be connected selectively to one of the N driver stages based on the time multiplexing scheme.

### CROSS-REFERENCE TO RELATED APPLICATIONS

The present application is a continuation of, and claims benefit under 35 USC 120 to, international application No. PCT/EP2024/070878, filed Jul. 23, 2024, which claims benefit under 35 USC 119 of German Application No. 10 2023 207 368.4, filed Aug. 1, 2023. The entire disclosure of each of these applications is incorporated by reference herein.

### FIELD

The present disclosure relates to a drive device for driving a plurality of actuator elements for actuating optical elements of an optical system, to an optical system comprising such a drive device, and to a lithography apparatus comprising such an optical system.

### BACKGROUND

Microlithography apparatuses are known which have actuatable optical elements, such as, for example, microlens element arrays or micromirror arrays. Microlithography is used to produce microstructured components, for example integrated circuits. The microlithography process is carried out using a lithography apparatus comprising an illumination system and a projection system.

Driven by the desire for ever smaller structures in the production of integrated circuits, EUV lithography apparatuses that use light with a wavelength in the range from 0.1 nm to 30 nm, for example 13.5 nm, are currently under development. Since most materials absorb light of this wavelength, EUV lithography apparatuses typically use reflective optics, which is to say mirrors, instead of—as previously—refractive optics, which is to say lens elements.

The image of a mask (reticle) illuminated by way of the illumination system is projected here by way of the projection system onto a substrate, for example a silicon wafer, which is coated with a light-sensitive layer (photoresist) and arranged in the image plane of the projection system, in order to transfer the mask structure to the light-sensitive coating of the substrate. The imaging of the mask on the substrate is able to be improved by way of actuatable optical elements. By way of example, wavefront aberrations during exposure, which result in magnified and/or blurred imaging, are able to be compensated for.

For example, a MEMS actuator (MEMS; microelectromechanical system) or a PMN actuator (PMN; lead magnesium niobate) may be used as actuator. A PMN actuator enables distance positioning in the sub-micrometre range or sub-nanometre range. In this case, the actuator, having actuator elements stacked one on top of another, experiences a force that causes a specific linear expansion as a result of a DC voltage being applied. The position set by way of the DC voltage (DC; direct current) may be adversely influenced by external electromechanical crosstalk at the fundamentally arising resonance points of the actuator driven by the DC voltage. MEMS mirrors and actuators suitable for driving them are described for example in DE 10 2016 213 025 A1. For example, an actuator can have a plurality of actuator elements for tilting the MEMS mirror in multiple axes.

By way of example, two actuator elements can be used for each mirror axis. As a result, several million actuator elements can be used in lithography apparatuses. It is worth noting here that over 40% of the electric power of an optical system of a lithography apparatus may arise at the actuator drive elements of the optical elements.

Due to the high number of optical elements in optical systems of lithography apparatuses, the associated high number of actuators for driving the optical elements and the desired relatively high drive voltage of for example 140 V, a relatively high thermal load can arise during driving, this being generally undesirable, especially in the vacuum housing of a lithography apparatus.

### SUMMARY

The present disclosure seeks to improve the driving of a plurality of actuator elements for actuating optical elements of an optical system.

According to a first aspect, the disclosure proposes a drive device for a plurality of actuator elements for actuating optical elements of an optical system. The drive device comprises:
N driver stages controlled by way of a time multiplex signal determined by a time multiplexing scheme, wherein the respective driver stage of the N driver stages is assigned to one of the N actuator elements and a specific time slot of the time multiplex signal, and has an amplifier that is configured to amplify a signal component of the assigned time slot of the time multiplex signal so as to form a drive voltage for driving the assigned actuator element, with N≥2, and
a control loop, the feedback branch of which has a voltage divider that is able to be connected selectively to one of the N driver stages based on the time multiplexing scheme.

A time multiplexing scheme here for example means that each of the N driver stages is assigned a fixed time slot of the time multiplex period of the time multiplex signal. If for example N=4, then the drive device has four driver stages for driving four actuator elements and the multiplex frame accordingly has four time slots. By way of example, the first time slot of the multiplex frame is then assigned to the first driver stage, the second time slot of the multiplex frame is assigned to the second driver stage, the third time slot of the multiplex frame is assigned to the third driver stage, and the fourth time slot is assigned to the fourth driver stage. Any other periodically repeating assignment of the time slots in a time multiplex period is likewise possible.

For the duration of the respective time slot, the respective driver stage assigned to the time slot can be driven, and its output signal, the respective drive voltage, can be fed back via the feedback branch of the control loop for regulation purposes.

The use of the driver stages controlled by the time multiplexing scheme and of the control loop, the feedback branch of which, containing a voltage divider, can be selectively connected to the current driver stage being driven in accordance with the time multiplexing scheme, can significantly reduce the thermal load caused by the present drive device when the actuator elements are driven compared to conventional solutions.

The large number of actuator elements (several million) in optical systems of a lithography apparatus and the relatively high desired drive voltage of for example 140 V, can result in a relatively large potential for saving on electric power consumption and accompanying thermal load.

The actuator is for example a MEMS actuator, an electrostatic (capacitive) actuator or a piezo actuator, for example a PMN actuator (PMN; lead magnesium niobate) or a PZT actuator (PZT; lead zirconate titanate) or a LiNbO3 actuator (lithium niobate). The actuator is configured, for example, to actuate an optical element of the optical system. Examples of such an optical element include lens elements, mirrors, for example micromirrors or MEMS mirrors, and adaptive mirrors.

The optical system can be a projection optical unit of the lithography apparatus or projection exposure apparatus. However, the optical system may also be an illumination system. The projection exposure apparatus may be an EUV lithography apparatus. EUV stands for “extreme ultraviolet” and refers to a wavelength of the operating light of between 0.1 nm and 30 nm. The projection exposure apparatus may also be a DUV lithography apparatus. DUV stands for “deep ultraviolet” and refers to a wavelength of the working light of between 30 nm and 250 nm.

According to one embodiment, the drive device has an output-side switch at the output of the amplifier of the respective driver stage. The output-side switches of the driver stages are coupled to the voltage divider via a first node here.

In an example, at a specific time, only one of the output-side switches of the driver stages is ever closed, so as to ensure that, at this time, only the driver stage assigned to the closed switch is coupled to the voltage divider via the first node. If for example the first time slot of the multiplex frame of the time multiplex signal is assigned to the first driver stage, then the output-side switch of the first driver stage is closed at the time of the first time slot, all other output-side switches are open and thus only the first driver stage is coupled to the voltage divider via the first node, thereby ensuring feedback of the output signal from the first driver stage via the feedback branch of the control loop.

According to an embodiment, the voltage divider is designed as a capacitive voltage divider or as a resistive voltage divider.

According to an embodiment, the drive device has:
a D/A converter that is configured to convert a digital representation, received on the input side, of the time multiplex signal into an analogue time multiplex signal, and to provide the analogue time multiplex signal at a second node on the output side, and
a differential amplifier, the non-inverting input of which is coupled to the second node and the inverting input of which is coupled to the centre tap of the voltage divider, and that is configured to amplify a difference between the analogue time multiplex signal present at the non-inverting input and a voltage provided across the centre tap and, depending thereon, to provide an amplified time multiplex drive signal at a third node on the output side.

The N driver stages can be connected in parallel between the third node and the first node, wherein a respective input-side switch, assigned to the amplifier, for selectively connecting the amplifier to the output of the differential amplifier is arranged between the third node and the amplifier of the respective driver stage.

Provision can be made for a control unit that is configured to control the switches of the driver stages in accordance with the time multiplexing scheme. The control unit can be implemented for example in software, as a discrete circuit or as an ASIC, and controls the switches of the driver stages. A discrete circuit can be for example a circuit constructed on a circuit board and comprise standard components, for example comprising resistors, transistors, capacitors, operational amplifiers and the like.

A holding capacitor for holding the level of the provided time multiplex drive signal in the open state of the assigned input-side switch can be connected between the node connecting the amplifier of the respective driver stage and the respective assigned input-side switch and ground.

The above embodiment can use time multiplexing of the voltage divider for multiple driver stages. By way of example, the drive device may be implemented on an ASIC, which for example drives nine MEMS mirrors. Assuming that four actuator elements are provided for driving a MEMS mirror, it follows that the present drive device is able to drive 36 actuator elements. In the present embodiment, the control loop can be an analogue control loop having an additional capacitor, the holding capacitor, for holding the voltage level. The present embodiment comprising the analogue control loop can be optimum with regard to chip footprint optimization.

The control unit of the drive device can ensure that only that amplifier of the selected amplifier stage selected in accordance with the time multiplexing scheme is connected to the voltage divider. The differential amplifier in this case can set the output of the currently selected amplifier to the desired output voltage. The input voltage for the desired output voltage can be kept constant by the holding capacitor, while the differential amplifier is not connected to the corresponding amplifier. This embodiment can reduce the energy consumption.

According to an embodiment, the drive device has:
an A/D converter arranged in the feedback branch, coupled to the centre tap of the voltage divider, and configured to convert the voltage provided across the centre tap of the voltage divider into a digital signal representing the provided voltage, and
a digital controller coupled to the A/D converter, and configured to provide a digital signal representing a difference between a digital representation of the time multiplex signal and the digital signal provided by the A/D converter at a seventh node on the output side.

In this embodiment, a substantial part of the control loop can be implemented in the digital domain, here by the digital controller. Leakage currents are therefore not relevant here. This embodiment can be desirable when complex digital logic, such as for example microcontrollers and/or FPGAs, is already available in the system. The ability to set the digital controller, for example on demand, can make it possible to further reduce energy consumption in some applications.

According to an embodiment, the respective driver stage has:
a storage unit, coupled to the seventh node, for buffer-storing a signal component of the time slot, assigned to the driver stage, of the digital signal provided at the seventh node,
a D/A converter, connected downstream of the storage unit, for converting the signal component provided by the storage unit into an analogue drive signal, and
the amplifier, connected downstream of the D/A converter, for amplifying the analogue drive signal into the drive voltage for driving the assigned actuator element.

The use of one D/A converter per driver stage can result in increased flexibility in terms of scaling and update rate. A readjustment may be carried out depending on the tilt angle and movement of the axis. In general, leakage currents are of no consequence here.

According to an embodiment, the digital controller is designed as a microcontroller or as an FPGA or as an application-specific integrated digital circuit (ASIC).

According to an embodiment, provision is made for a control unit that is configured to control the switches and the storage units of the driver stages in accordance with the time multiplexing scheme. The control unit can be implemented for example in software, as a discrete circuit or as an ASIC, and controls the switches and the storage units. A discrete circuit is for example a circuit constructed on a circuit board and comprising standard components, for example comprising resistors, transistors, capacitors, operational amplifiers and the like.

According to an embodiment, the drive device has:
a D/A converter that is configured to convert a digital representation, received on the input side, of the time multiplex signal into an analogue time multiplex signal, and to provide the analogue time multiplex signal on the output side,
a comparator arranged in the feedback branch, coupled to the centre tap of the voltage divider via a first input node, and configured to provide a comparison result on the output side based on a comparison between the voltage provided across the centre tap of the voltage divider and the analogue time multiplex signal provided by the D/A converter, and
a successive approximation controller coupled to the comparator, and configured to provide a digital signal, based on a successive approximation using a digital representation of the time multiplex signal and the comparison result, at a seventh node on the output side.

The analogue time multiplex signal provided by the D/A converter can serve here as a target value (or reference value) for the successive approximation control.

According to an embodiment, the respective driver stage has:
a storage unit, coupled to the seventh node, for buffer-storing a signal component of the time slot, assigned to the driver stage, of the digital signal provided at the seventh node,
a D/A converter, connected downstream of the storage unit, for converting the signal component provided by the storage unit into an analogue drive signal, and
the amplifier, connected to the D/A converter via a coupling node, for amplifying the analogue drive signal into the drive voltage for driving the assigned actuator element.

The respective coupling node can be connected to the second input node of the comparator via a respective switch.

Provision can be made for a control unit that is configured to control the switches in accordance with the time multiplexing scheme. The control unit can be implemented for example in software, as a discrete circuit or as an ASIC, and controls the switches. A discrete circuit is for example a circuit constructed on a circuit board and comprising standard components, for example comprising resistors, transistors, capacitors, operational amplifiers and the like. In the case of a software implementation, the control unit may be in the form of a computer program product, a function, a routine, part of a program code or an executable object.

In this embodiment, the control loop for the driver stages can also be implemented in the digital domain. In this case, the use of the successive approximation controller can reduce the complexity of the digital logic. The present successive approximation controller can work similarly to a SAR ADC (successive-approximation analogue-digital converter) and runs through the bits of the digital time multiplex signal, while the output voltage of the amplifier approaches the desired target value, that is to say the value of the analogue time multiplex signal provided by the D/A converter. The digital successive approximation controller can start by setting the MSB (most significant bit) to 1, and the comparator checks whether the output voltage of the amplifier, divided by the voltage divider, is greater than or less than the target value. If it is greater, the MSB is set to 0, otherwise it remains at 1. This operation can be repeated bit-by-bit from the MSB to the LSB (least significant bit). This type of voltage feedback may be performed on demand. This on-demand performance is able to further reduce power consumption.

According to a second aspect, the disclosure proposes an optical system comprising a number of actuatable optical elements, wherein each of the actuatable optical elements of the number is assigned a plurality N of actuator elements of an actuator, wherein each actuator is assigned a drive device for driving the actuator in accordance with the first aspect or in accordance with one of the embodiments of the first aspect.

The optical system comprises, for example, a micromirror array and/or a microlens element array having a multiplicity of optical elements that are actuatable independently of one another. In some embodiments, groups of actuators may be defined, wherein all actuators of a group are assigned the same drive device.

According to one embodiment, the optical system is in the form of an illumination optical unit or in the form of a projection optical unit of a lithography apparatus.

According to an embodiment, the optical system has a vacuum housing, in which the actuatable optical elements, the assigned actuators and the drive device are arranged.

According to a third aspect, the disclosure proposes a lithography apparatus having an optical system in accordance with the second aspect or in accordance with one of the embodiments of the second aspect.

The lithography apparatus is for example an EUV lithography apparatus, the working light of which is in a wavelength range of 0.1 nm to 30 nm, or a DUV lithography apparatus, the working light of which is in a wavelength range of 30 nm to 250 nm.

“A(n)” should not necessarily be understood as a restriction to exactly one element in the present case. Rather, a plurality of elements, such as for example two, three or more, may also be provided. Nor should any other numeral used here be understood to the effect that there is a restriction to exactly the stated number of elements. Rather, unless indicated otherwise, numerical deviations upwards and downwards are possible.

Further possible implementations of the disclosure also encompass not explicitly mentioned combinations of features or embodiments that are described above or hereinafter with respect to the exemplary embodiments. In this case, a person skilled in the art will also add individual aspects as improvements or supplementations to the respective basic form of the disclosure.

Further features, configurations and aspects of the disclosure are the subject of the dependent claims and also of the exemplary embodiments of the disclosure that are described hereinafter. The disclosure is explained in greater detail hereinafter on the basis of certain embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic illustration of one embodiment of an optical system;

FIG. 3 shows a schematic block diagram of a first embodiment of a drive device for driving a plurality of actuator elements for actuating optical elements of an optical system;

FIG. 4 shows a schematic diagram of one embodiment of a time multiplex signal determined in accordance with the time multiplexing scheme used in FIG. 3;

FIG. 5 shows a schematic block diagram of a second embodiment of a drive device for driving a plurality of actuator elements for actuating optical elements of an optical system; and

FIG. 6 shows a schematic block diagram of a third embodiment of a drive device for driving a plurality of actuator elements for actuating optical elements of an optical system.

### DETAILED DESCRIPTION

Unless indicated otherwise, elements that are identical or functionally identical have been provided with the same reference signs in the figures. Furthermore, it should be noted that the illustrations in the figures are not necessarily true to scale.

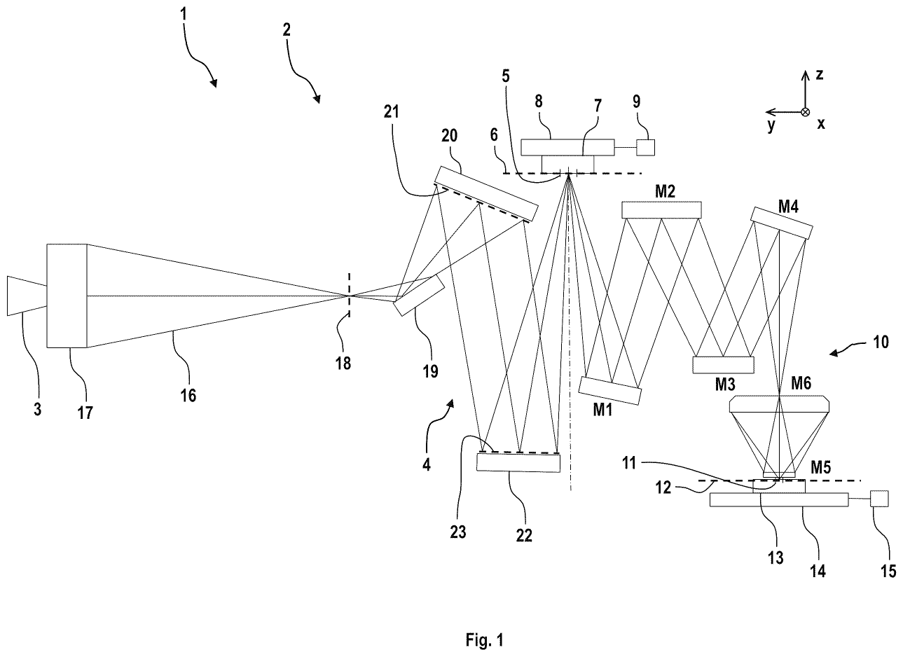

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In one alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs along the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 runs parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits for example EUV radiation 16, which is also referred to below as used radiation, illumination radiation or illumination light. For example, the used radiation 16 has a wavelength in the range between 5 nm and 30 nm. The light source 3 may be a plasma source, for example an LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emanating from the light source 3 is focused by a collector 17. The collector 17 may be a collector with one or more ellipsoidal and/or hyperboloidal reflection surfaces. The at least one reflection surface of the collector 17 may be impinged upon by the illumination radiation 16 with grazing incidence (abbreviated as:
GI), which is to say with angles of incidence greater than 45°, or with normal incidence (abbreviated as: NI), which is to say with angles of incidence less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. As an alternative or in addition, the deflection mirror 19 may be designed as a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror.

The first facet mirror 20 comprises a multiplicity of individual first facets 21, which may also be referred to as field facets. Only some of these first facets 21 are shown in FIG. 1 by way of example.

The first facets 21 may be designed as macroscopic facets, for example as rectangular facets or as facets with an arcuate edge contour or an edge contour of part of a circle. The first facets 21 may be in the form of plane facets or alternatively in the form of convexly or concavely curved facets.

As is known for example from DE 10 2008 009 600 A1, the first facets 21 themselves may also each be composed of a multiplicity of individual mirrors, for example a multiplicity of micromirrors. The first facet mirror 20 may for example be in the form of a microelectromechanical system (MEMS system). For details, reference is made to DE 10 2008 009 600 A1.

Between the collector 17 and the deflection mirror 19, the illumination radiation 16 runs horizontally, that is to say in the y-direction y.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal periphery, or may alternatively be facets composed of micromirrors. In this regard, reference is likewise made to DE 10 2008 009 600 A1.

The second facets 23 may have plane or, alternatively, convexly or concavely curved reflection surfaces.

The illumination optical unit 4 consequently forms a doubly faceted system. This fundamental principle is also referred to as a fly's eye condenser (or integrator).

It may be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit may be arranged in the beam path between the second facet mirror 22 and the object field 5, and contributes for example to the imaging of the first facets 21 into the object field 5. The transfer optical unit may have exactly one mirror or, alternatively, also two or more mirrors, which are arranged in succession in the beam path of the illumination optical unit 4. The transfer optical unit may for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so the illumination optical unit 4 may then have exactly two mirrors downstream of the collector 17, specifically the first facet mirror 20 and the second facet mirror 22.

The imaging of the first facets 21 into the object plane 6 by way of the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi may be designed as freeform surfaces without an axis of rotational symmetry. As an alternative, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, for example with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may for example have an anamorphic form. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, that is to say in a direction perpendicular to the scanning direction.

The projection optical unit 10 leads to a reduction in size of 8:1 in the y-direction y, that is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may for example result in illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is for example as homogeneous as possible. It can have a uniformity error of less than 2%. Field uniformity may be achieved by superimposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optical unit 4 that are illuminated in a defined manner may be achieved by a redistribution of the illumination channels.

Further aspects and details of the illumination of the object field 5 and for example of the entrance pupil of the projection optical unit 10 are described hereinafter. The projection optical unit 10 may have for example a homocentric entrance pupil. It may be accessible. It may also be inaccessible.

The entrance pupil of the projection optical unit 10 often cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area exhibits a finite curvature.

It may be the case that the projection optical unit 10 has different positions of the entrance pupil for the tangential beam path and for the sagittal beam path. In this case, an imaging element, for example an optical component of the transfer optical unit, should be provided between the second facet mirror 22 and the reticle 7. The different positions of the tangential entrance pupil and the sagittal entrance pupil are able to be taken into account using this optical element.

In the arrangement of the components of the illumination optical unit 4 illustrated in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

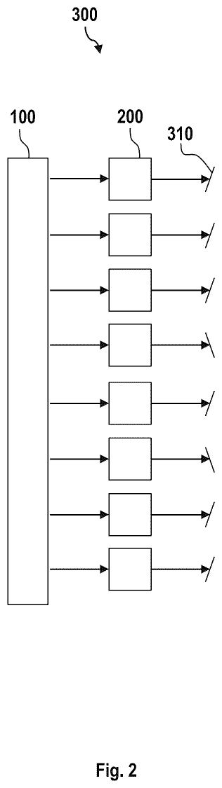

FIG. 2 shows a schematic illustration of one embodiment of an optical system 300 for a lithography apparatus or projection exposure apparatus 1, as shown in FIG. 1 for example. Additionally, the optical system 300 of FIG. 2 may also be used in a DUV lithography apparatus for example.

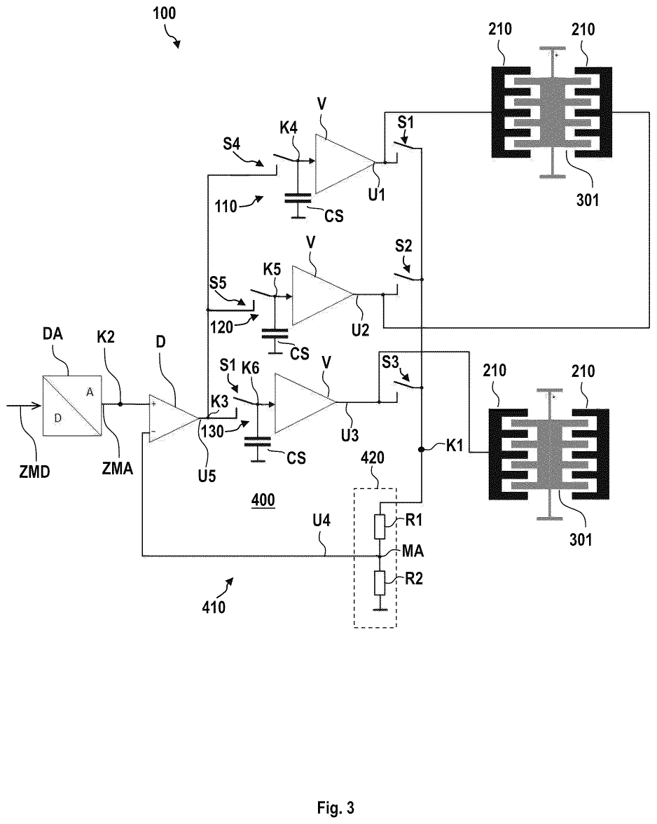

The optical system 300 of FIG. 2 has a plurality of actuatable optical elements 310. The optical system 300 is designed here as a micromirror array, wherein the optical elements 310 are micromirrors. Each micromirror 310 is actuatable by way of an assigned actuator 200. By way of example, a respective micromirror 310 may be tilted about two axes and/or displaced in one, two, or three spatial axes by way of the assigned actuator 200. For example, an actuator 200 has a plurality of actuator elements 210 (see FIGS. 3, 5 and 6) for tilting the micromirror 310 in multiple axes. The reference signs only of the topmost row of these elements are depicted, for reasons of clarity.

The drive device 100 drives the actuator elements 210 of the respective actuator 200, for example with a drive voltage U1, U2, U3 (see FIGS. 3, 5 and 6). This sets a position of the respective micromirror 310. The drive device 100 is described for example with reference to FIGS. 3, 5 and 6.

FIG. 3 illustrates a schematic block diagram of a first embodiment for driving a plurality N of actuator elements 210 for actuating optical elements 310 of an optical system 4, 10.

The optical element 310 illustrated in FIG. 3 is a MEMS mirror able to be displaced in two mutually orthogonal tilting axes. The MEMS mirror 310 in FIG. 3 is illustrated for each of the tilting axes in FIG. 3, and thus shown twice in FIG. 3. Two actuator elements 210 are provided for each of the two tilting axes. Four actuator elements 210 are thus provided for the MEMS mirror 310 in FIG. 3. As illustrated in FIG. 3, three of the four actuator elements 210 are driven by three driver stages 110-130 (with N=3). Without limiting generality, the fourth actuator element 210 may also be driven by a driver stage (not shown). In general, the drive device 100 has N driver stages 110-130 for driving N actuator elements 210.

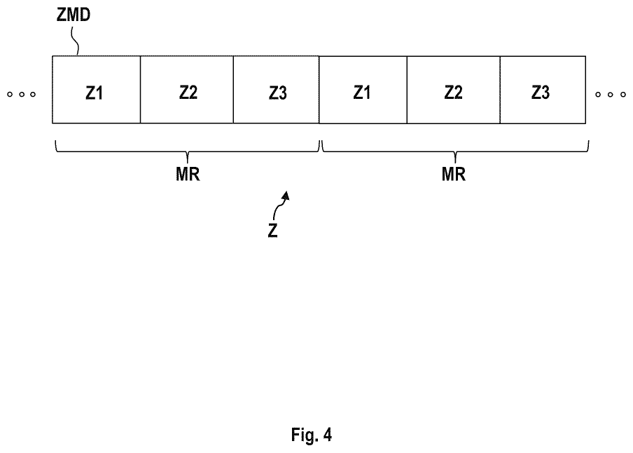

The driver stages 110-130 of the drive device 100 are controlled by way of a time multiplex signal ZMD, ZMA determined by a time multiplexing scheme Z (see FIG. 4). The determined time multiplex signal ZMD, ZMA may be in the form of a digital time multiplex signal ZMD or an analogue time multiplex signal ZMA.

As also shown in FIG. 3, each of the driver stages 110-130 is assigned to one of the actuator elements 210. Furthermore, each of the driver stages 110-130 is assigned to a specific time slot Z1-Z3 of the time multiplex signal ZMD, ZMA.

A time multiplexing scheme Z here for example means that each of the three driver stages 110-130 is assigned a fixed time slot Z1-Z3 of the time multiplex frame MR or of the time multiplex period of the time multiplex signal ZMD. In this regard, FIG. 4 shows one embodiment of a time multiplex signal ZMD determined in accordance with the time multiplexing scheme Z used in FIG. 3. With regard to the allocations of the time slots Z1-Z3 in the multiplex frame MR, it does not matter whether the time multiplex signal is in the form of a digital time multiplex signal ZMD or an analogue time multiplex signal ZMA. If, as in the example of FIGS. 3 and 4, the drive device 100 has three driver stages 110-130 for driving three actuator elements 210, then the time multiplex frame MR accordingly has three time slots Z1-Z3. By way of example, the first time slot Z1 of the multiplex frame MR is then assigned to the first driver stage 110, the second time slot Z2 of the multiplex frame MR is assigned to the second driver stage 120 and the third time slot Z3 of the multiplex frame MR is assigned to the third driver stage.

Furthermore, the respective driver stage 110-130 has an amplifier V that is configured to amplify a signal component of the assigned time slot Z1-Z3 of the time multiplex signal ZMD, ZMA so as to form a drive voltage U1-U3 for driving the assigned actuator element 210.

As also shown in FIG. 3, the drive device 100 has a control loop 400, the feedback branch 410 of which has a voltage divider 420 that is able to be connected selectively to one of the three driver stages 110-130 based on the time multiplexing scheme Z. The voltage divider 410 has a series connection of two resistors R1, R2. The node between the two series-connected resistors R1, R2 forms the centre tap MA of the voltage divider 420. In FIG. 3, the voltage divider 420 is designed as a resistive voltage divider. As an alternative, the voltage divider 420 may also be designed as a capacitive voltage divider.

With regard to the selection of the respective driver stage 110-130 in accordance with the time multiplexing scheme Z and thus the selective connection of the selected one of the three driver stages 110-130 to the voltage divider 420, the respective driver stage 110-130 has an output-side switch S1-S3. The respective output-side switch S1-S3 is arranged here at the output of the amplifier V of the respective driver stage 110-130. As shown in FIG. 3, the output-side switches S1-S3 of the driver stages 110-130 are coupled to the voltage divider 420 via a first node K1. Provision is furthermore made for a control unit (not shown) that is configured to drive the switches S1-S3 in accordance with the time multiplexing scheme Z, such that in each case the driver stage 110-130 driven by the time multiplex signal ZMD, ZMA is connected to the voltage divider 420 via the node K1.

If for example, at a time of the time slot Z1 (see FIG. 4), the first driver stage 110 is driven by way of the time multiplex signal ZMD, ZMA, then the switch S1 is closed by the control unit for the period of the time slot Z1, whereas the switches S2 and S3 remain open, as a result of which the output of the amplifier V of the first driver stage 110 is connected to the voltage divider 420 via the node K1. In the subsequent period corresponding to the time slot Z2, the second driver stage 120 is driven by way of the time multiplex signal ZMD, ZMA and the switch S2 is closed, whereas the switches S1 and S3 are open, such that the output of the amplifier V of the second driver stage 120 is connected to the voltage divider 420 via the first node K1. The same applies for the third time slot Z3 and the driving of the third driver stage 130. It should be noted that N, in the embodiments, is between 2 and 40 (2≤N≤40).

As also illustrated in FIG. 3, the drive device 100 may have a D/A converter DA. The D/A converter DA is configured to convert a digital representation ZMD, received on the input side, of the time multiplex signal into an analogue time multiplex signal ZMA, and to provide the analogue time multiplex signal ZMA at a second node K2 on the output side. A differential amplifier D is connected downstream of the D/A converter DA. The non-inverting input of the differential amplifier D is coupled to the second node K2. The inverting input of the differential amplifier D is coupled to the centre tap MA of the voltage divider 420. The differential amplifier D is configured to amplify a difference between the analogue time multiplex signal ZMA present at the non-inverting input and a voltage U4 provided across the centre tap MA and, depending thereon, to provide an amplified time multiplex drive signal U5 at a third node K3 on the output side.

The three driver stages 110-130 of the drive device 100 are connected in parallel between the third node K3 and the first node K1. Furthermore, a respective input-side switch S4-S6, assigned to the amplifier V, for selectively connecting the amplifier V to the output of the differential amplifier D is arranged between the third node K3 and the amplifier V of the respective driver stage 110-130. The abovementioned control unit is configured here to control not only the switches S1-S3 discussed above, but also the input-side switches S4-S6 of the driver stages 110-130 in accordance with the time multiplexing scheme Z.

As also shown in FIG. 3, a holding capacitor CS is coupled between the node K4-K6 connecting the amplifier V of the respective driver stage 110-130 and the respective assigned input-side switch S4-S6 and ground. The holding capacitor CS is configured to hold the level of the provided time multiplex signal U5 in the open state of the assigned input-side switch S4-S6.

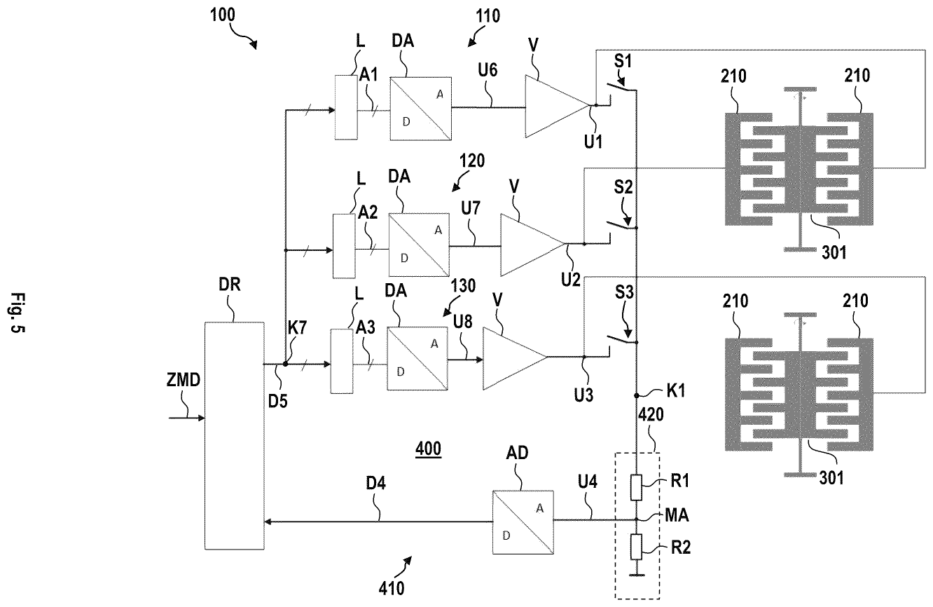

FIG. 5 shows a schematic block diagram of a second embodiment of a drive device 100 for driving a plurality N of actuator elements 210 for actuating optical elements 310 of an optical system 4, 10. Without limiting generality, the drive device 100 of FIG. 5 also drives three actuator elements 210 for actuating a MEMS mirror 310.

Like the first embodiment according to FIG. 3, the second embodiment of the drive device 100 according to FIG. 5 has N (with N=3 in FIG. 5) driver stages 110-130 controlled by way of a time multiplex signal ZMD determined by a time multiplexing scheme Z (see FIG. 4). The respective driver stage 110-130 is assigned to one of the actuator elements 210 and a specific time slot Z1-Z3 of the time multiplex signal ZMD. The assignment is, for example, the same as explained with reference to FIGS. 3 and 4. The respective driver stage 110-130 has-like in FIG. 3—a n amplifier V that is configured to amplify a signal component A1-A3 of the assigned time slot Z1-Z3 of the time multiplex signal ZMD so as to form a drive voltage U1-U3 for driving the assigned actuator element 210.

Like all of the embodiments of the present drive device 100, the embodiment according to FIG. 5 also has a control loop 400, the feedback branch 410 of which has a voltage divider 420 that is able to be connected selectively to one of the driver stages 110-130 via the node K1 based on the time multiplexing scheme Z. Like in all of the embodiments of the drive device 100, provision is likewise made for an output-side switch S1-S3 at the output of the amplifier V of the respective driver stage 110-130. The output-side switches S1-S3 of the driver stages 110-130 are coupled to the voltage divider 420 via the first node K1.

The drive device 100 of FIG. 5 also has a A/D converter AD arranged in the feedback branch 410 of the control loop 400 and coupled to the centre tap MA of the voltage divider 420. The A/D converter AD is configured to convert the voltage U4 provided across the centre tap MA of the voltage divider 420 into a digital signal D4 representing the provided voltage U4.

Furthermore, the drive device 100 of FIG. 5 comprises a digital controller DR coupled to the A/D converter AD. The digital controller DR is configured to provide a digital signal D5 representing a difference between a digital time multiplex signal ZMD and the digital signal D4 provided by the A/D converter AD at a seventh node K7 on the output side.

The respective driver stage 110-130 of FIG. 5 also has a storage unit L coupled to the seventh node K7 for buffer-storing a signal component A1-A3 of the time slot Z1-Z3, assigned to the driver stage 110-130, of the digital signal D5 provided at the seventh node K7. The digital signal D5 is a time multiplex signal in accordance with the received time multiplex signal ZMD, and is structured in accordance with the time multiplex frame MR (see FIG. 3).

The respective driver stage 110-130 of FIG. 5 also has a D/A converter DA, connected downstream of the storage unit L, for converting the signal component A1-A3 provided by the storage unit L into an analogue drive signal U6-U8. The respective driver stage 110-130 of FIG. 5 also has an amplifier V, connected downstream of the D/A converter DA, for amplifying the analogue drive signal U6-U8 into the drive voltage U1-U3 for driving the assigned actuator element 210.

In addition, the drive device 100 according to FIG. 5 has a control unit (not shown) that is configured to control the switches S1-S3 and the storage units L of the driver stages 110-130 in accordance with the time multiplexing scheme Z.

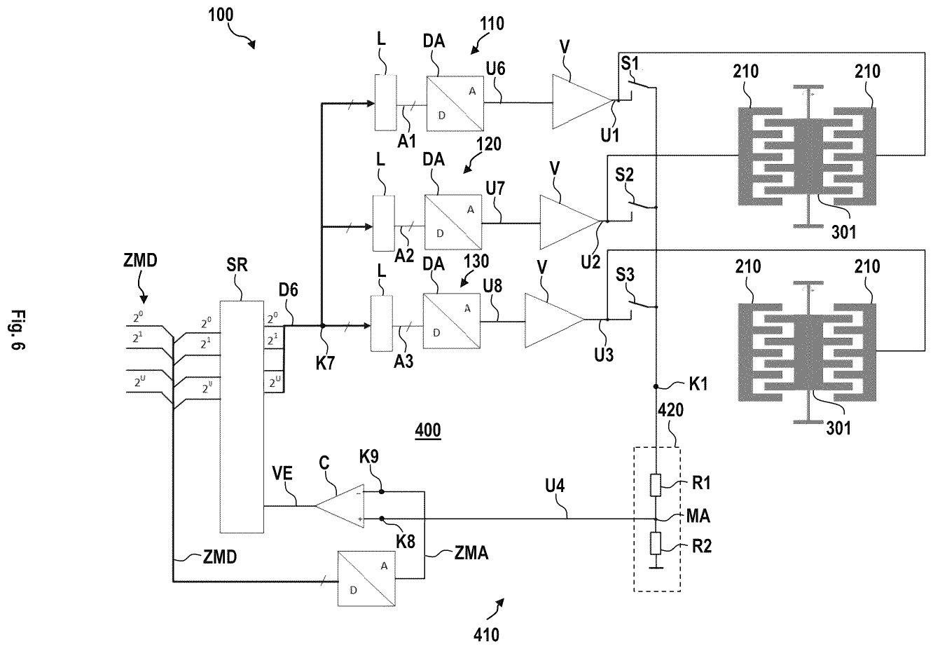

FIG. 6 illustrates a schematic block diagram of a third embodiment of a drive device 100 for driving a plurality N of actuator elements 210 for actuating optical elements 310 of an optical system 4, 10.

Like the first embodiment and the second embodiment according to FIG. 3-5, the drive device of FIG. 6 has N driver stages 110-130 controlled by way of a time multiplex signal ZMD determined by a time multiplexing scheme Z (see FIG. 4), wherein the respective driver stage 110-130 of the N driver stages 110-130 is assigned to one of the N actuator elements 210 and a specific time slot Z1-Z3 of the time multiplex signal ZMD, and has an amplifier V. The amplifier V is configured to amplify a signal component A1-A3 of the assigned time slot Z1-Z3 of the time multiplex signal ZMD so as to form a drive voltage U1-U3 for driving the assigned actuator element 210.

In addition, the drive device 100 according to FIG. 6 also has a control loop 400, the feedback branch 410 of which has a voltage divider 420 that is able to be selectively connected to one of the N driver stages 110-130 based on the time multiplexing scheme Z. Also, like in all of the embodiments of the drive device 100, in the embodiment according to FIG. 6, provision is made for an output-side switch S1-S3 at the output of the amplifier V of the respective driver stage 110-130. The output-side switches S1-S3 of the driver stages 110-130 are coupled to the voltage divider 420 via the first node K1.

In addition, the drive device 100 according to FIG. 6 has a D/A converter DA that is configured to convert a digital representation ZMD, received on the input side, of the time multiplex signal into an analogue time multiplex signal ZMA, and to provide the analogue time multiplex signal ZMA on the output side.

Furthermore, the drive device 100 according to FIG. 6 has a comparator C arranged in the feedback branch 410 and coupled to the centre tap MA of the voltage divider 420 via a first input node K8 (non-inverting input). The comparator C is configured to provide a comparison result VE on the output side based on a comparison between the voltage U4 provided across the centre tap MA of the voltage divider 420 and the analogue time multiplex signal ZMA provided by the D/A converter DA. The comparator C receives the analogue time multiplex signal ZMA provided by the D/A converter DA via its second input node K9 (inverting input).

The drive device 100 according to FIG. 6 also has a successive approximation controller SR coupled to the comparator C. The successive approximation controller SR is configured to provide a digital signal D6, based on a successive approximation using a digital representation ZMD of the time multiplex signal and the comparison result VE, at a seventh node K7 on the output side. The analogue time multiplex signal ZMA provided by the D/A converter DA serves here as a target value (or reference value) for the successive approximation control.

The successive approximation controller SR works similarly to a SAR ADC (successive-approximation analogue-digital converter) and runs through the bits of the digital time multiplex signal ZMD, while the output voltage, for example U1, of the amplifier V approaches the desired target value, that is to say the value of the analogue time multiplex signal ZMA provided by the D/A converter DA. The digital successive approximation controller SR starts by setting the MSB (most significant bit) to 1, and the comparator C checks whether the output voltage U1 of the amplifier V, divided by the voltage divider 420, is greater than or less than the target value. If it is greater, the MSB is set to 0, otherwise it remains at 1. This operation is repeated bit-by-bit from the MSB to the LSB (least significant bit).

The respective driver stage 110-130 of the drive device 100 according to FIG. 6 comprises a storage unit L, coupled to the seventh node K7, for buffer-storing a signal component A1-A3 of the time slot Z1-Z3, assigned to the driver stage 110-130, of the digital signal D6 provided at the seventh node K7, a D/A converter DA, connected downstream of the storage unit L, for converting the signal component A1-A3 provided by the storage unit L into an analogue drive signal U6-U8, and an amplifier V, connected downstream of the D/A converter DA, for amplifying the analogue drive signal U6-U8 into the drive voltage U1-U3 for driving the assigned actuator element 210.

The drive device 100 according to FIG. 6 has a control unit (not shown) that is configured to control the switches S1-S3 in accordance with the time multiplexing scheme Z.

Although the present disclosure has been described on the basis of exemplary embodiments, it may be modified in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Drive device
110 First driver stage
120 Second driver stage
130 Third driver stage
200 Actuator
210 Actuator element
300 Optical system
310 Optical element
400 Control loop
410 Feedback branch
420 Voltage divider
A1 Signal component of the time slot Z1, assigned to the first driver stage, of the digital signal
A2 Signal component of the time slot Z2, assigned to the second driver stage, of the digital signal
A3 Signal component of the time slot Z3, assigned to the third driver stage, of the digital signal
C Comparator
CS Holding capacitor
D4 Digital signal
D5 Digital signal
D6 Digital signal
DR Digital controller
K1 First node
K2 Second node
K3 Third node
K4 Fourth node
K5 Fifth node
K6 Sixth node
K7 Seventh node
K8 Eighth node
K9 Ninth node
L Storage unit, latch
MA Centre tap
MR Multiplex frame
R1 Resistor
R2 Resistor
S1 Output-side switch at the output of the first driver stage
S2 Output-side switch at the output of the second driver stage
S3 Output-side switch at the output of the third driver stage
S4 Input-side switch
S5 Input-side switch
S6 Input-side switch
SR Successive approximation controller
U1 Drive voltage (provided by the first driver stage)
U2 Drive voltage (provided by the second driver stage)
U3 Drive voltage (provided by the third driver stage)
U4 Voltage provided at the centre tap of the voltage divider
U5 Amplified time multiplex drive signal
U6 Analogue drive signal for driving the amplifier of the first driver stage
U7 Analogue drive signal for driving the amplifier of the second driver stage
U8 Analogue drive signal for driving the amplifier of the third driver stage
V Amplifier
VE Comparison result
Z Time multiplexing scheme
Z1 Time slot (assigned to the first driver stage)
Z2 Time slot (assigned to the second driver stage)
Z3 Time slot (assigned to the third driver stage)
ZMA Analogue time multiplex signal
ZMD Digital time multiplex signal

What is claimed is:

1. A drive device configured to drive a plurality N of actuator elements to actuate optical elements of an optical system, the drive device comprising:
N driver stages controllable via a time multiplex signal determinable by a time multiplexing scheme, the N driver stages comprising a first driver stage, the first driver stage being assigned to a first actuator element of the N actuator elements, the first driver stage being assigned to a first time slot of the time multiplex signal, the first driver stage comprising a first amplifier configured to amplify a signal component of the first time slot of the time multiplex signal to provide a drive voltage to drive the first actuator element; and
a control loop comprising a feedback branch, the feedback branch comprising a voltage divider selectively connectable to one of the N driver stages based on the time multiplexing scheme,
wherein N is at least two.

2. The drive device of claim 1, further comprising an output-side switch at an output of the first amplifier, wherein the output-side switch is coupled to the voltage divider via a first node.

3. The drive device of claim 2, wherein the voltage divider comprises a capacitive voltage divider, or the voltage divider comprises a resistive voltage divider.

4. The drive device of claim 2, further comprising:
a D/A converter configured to: i) convert a digital representation of the time multiplex signal, received on an input side of the D/A converter, into an analogue time multiplex signal; and ii) provide the analogue time multiplex signal to a second node which is on an output side of the D/A converter; and
a differential amplifier comprising: i) a non-inverting input coupled to the second node; ii) an inverting input coupled to a center tap of the voltage divider,
wherein the differential amplifier configured to: i) amplify a difference between the analogue time multiplex signal at the non-inverting input and a voltage across the center tap; and ii) depending on the difference, provide an amplified time multiplex drive signal at a third node which is on an output side of the differential amplifier.

5. The drive device of claim 4, wherein:
the N driver stages are connected in parallel between the third node and the first node; and
a respective input-side switch, assigned to the amplifier to selectively connect the amplifier to the output of the differential amplifier, is between the third node and the amplifier of the respective driver stage.

6. The drive device of claim 5, further comprising a control unit configured to control the switches of the driver stages in accordance with the time multiplexing scheme.

7. The drive device of claim 5, further comprising a holding capacitor configured to hold a level of the time multiplex drive signal in an open state of the assigned input-side switch is connected between a node connecting the amplifier of the respective driver stage and the respective assigned input-side switch and ground.

8. The drive device of claim 2, further comprising:
an A/D converter in the feedback branch, the A/D converter being coupled to the center tap of the voltage divider, the A/D converter being configured to convert the voltage provided across the center tap into a digital signal representing the provided voltage; and
a digital controller coupled to the A/D converter, the digital controller being configured to provide a digital signal representing a difference between a digital representation of the time multiplex signal and the digital signal provided by the A/D converter at a node on an output side of the digital controller.

9. The drive device of claim 8, wherein the respective driver stage comprises:
a storage unit coupled to the node on the output side of the digital controller to buffer-store a signal component of the time slot, assigned to the driver stage, of the digital signal provided at the node on the output side of the digital controller; and
a D/A converter connected downstream of the storage unit to convert the signal component provided by the storage unit into an analogue drive signal,
wherein the amplifier is connected downstream of the D/A converter to amplify the analogue drive signal into the drive voltage to drive the assigned actuator element.

10. The drive device of claim 8, wherein the digital controller comprises a member selected from the group consisting of a microcontroller, an FPGA, or an application-specific integrated digital circuit.

11. The drive device of claim 9, further comprising a control unit that configured to control the switches and the storage units of the driver stages in accordance with the time multiplexing scheme.

12. The drive device of claim 2, further comprising:
a comparator in the feedback branch, the comparator being coupled to the center tap via an input node, the comparator being configured to provide a comparison result on an output side of the comparator based on a comparison between the voltage provided across the center tap and an analogue drive signal received via an input node of the comparator, the comparator being present at the input of the amplifier of the driver stage respectively selected in accordance with the time multiplexing scheme; and
a successive approximation controller coupled to the comparator, the successive approximation controller being configured to provide a digital signal, based on a successive approximation using a digital representation of the time multiplex signal and the comparison result, at a node on an output side of the successive approximation controller.

13. The drive device of claim 12, wherein the respective driver stage comprises:
a storage unit coupled to the node on the output side of the successive approximation controller to buffer-store a signal component of the time slot, assigned to the driver stage, of the digital signal provided at the node on the output side of the successive approximation;
a D/A converter connected downstream of the storage unit to convert the signal component provided by the storage unit into an analogue drive signal; and
the amplifier is connected to the D/A converter via a coupling node to amplify the analogue drive signal into the drive voltage to drive the assigned actuator element.

14. The drive device of claim 13, wherein the respective coupling node is connected to the input node of the comparator via a respective switch.

15. The drive device of claim 14, further comprising a control unit configured to control the switches in accordance with the time multiplexing scheme.

16. The drive device of claim 1, wherein the voltage divider comprises a capacitive voltage divider, or the voltage divider comprises a resistive voltage divider.

17. An optical system, comprising:
an actuator comprising a plurality of actuator elements;
a number of optical elements, each of optical element assigned more than one of the plurality of actuator elements,
wherein each actuator is assigned a drive device according to claim 1.

18. The system of claim 17, wherein the optical system comprises an illumination optical unit of a lithography apparatus, or the optical system comprises a projection optical unit of a lithography apparatus.

19. A lithography apparatus, comprising:
an illumination optical unit; and
a projection optical unit,
wherein the illumination optical unit comprises:
an actuator comprising a plurality of actuator elements;
a number of optical elements, each of optical element assigned more than one of the plurality of actuator elements, and
wherein each actuator is assigned a drive device according to claim 1.

20. A lithography apparatus, comprising:
an illumination optical unit; and
a projection optical unit,
wherein the projection optical unit comprises:
an actuator comprising a plurality of actuator elements;
a number of optical elements, each of optical element assigned more than one of the plurality of actuator elements, and
wherein each actuator is assigned a drive device according to claim 1.
